(19) United States
(12) Patent Application Publication
(10) Pub. No.: US 2013/0234575 A1
(43) Pub. Date: Sep. 12, 2013

(54) METHOD AND SYSTEM FOR PROVIDING AN ELECTRONIC EQUIPMENT CABINET USABLE FOR STORING RESERVE POWER BATTERIES

(71) Applicant: INTELLIBATT, LLC, San Rafael, CA (US)

(72) Inventors: Stephen Dean Cotton, San Rafael, CA (US); Shad Jon Smith, San Anselmo, CA (US); Ronnie Lim, Elk Grove, CA (US); John Michael Brinck, San Rafael, CA (US)

(73) Assignee: INTELLIBATT, LLC, San Rafael, CA (US)

(21) Appl. No.: 13/794,051

(22) Filed: Mar. 11, 2013

Related U.S. Application Data
(60) Provisional application No. 61/609,348, filed on Mar. 11, 2012.

(51) Int. Cl. H05K 5/02; H05K 5/03

(52) U.S. Cl. CPC H05K 5/0247; H05K 5/0213; H05K 5/03
USPC 312/236; 312/223.1; 312/223.6

(57) ABSTRACT

An electronic equipment cabinet is provided. The cabinet includes a plurality of sidewalls and a plurality of shelves. The sidewalls include a pair of opposing sidewalls. Each of the opposing sidewalls includes a plurality of shelf mounting points. The shelves are configured to be received at the shelf mounting points such that the shelves are configurable to accommodate components.

### CROSS-REFERENCE TO RELATED APPLICATIONS

This application claims the benefit of U.S. Provisional Application No. 61/609,348, filed on Mar. 11, 2012 and is assigned to the assignee of the present invention and incorporated herein by reference.

### BACKGROUND

Electronic equipment cabinets are used to store various electronic components, including but not limited to batteries. For example, batteries may be used in providing reserve power for server farms and/or other businesses for which reliable backup power is desired. Such batteries may be housed in electronic equipment cabinets adapted for use with batteries and are termed battery cabinets herein. Although, such cabinets are useful in storing electronic components, improvements are desired. Accordingly, what is needed is a system and method for improving the storage of electronic components such as reserve power batteries.

### SUMMARY

An electronic equipment cabinet is provided. The cabinet includes a plurality of sidewalls and a plurality of shelves. The sidewalls include a pair of opposing sidewalls. Each of the opposing sidewalls includes a plurality of shelf mounting points. The shelves are configured to be received at the shelf mounting points such that the shelves are configurable to accommodate components

### BRIEF DESCRIPTION OF SEVERAL VIEWS OF THE DRAWINGS

FIG. 1 depicts a perspective view of an exemplary embodiment of an electronic equipment cabinet.

FIGS. 2A-2B depict exemplary embodiments possible battery arrangements in an electronic equipment cabinet.

FIG. 3 depicts a perspective view of an exemplary embodiment of the top of an open electronic equipment cabinet including cooling fans.

FIG. 4 depicts a perspective view of an exemplary embodiment of an open electronic equipment cabinet including an integrated battery monitoring system.

FIG. 5 depicts a perspective view of an exemplary embodiment of a portion of an electronic equipment cabinet including a cable tray.

FIG. 6 depicts a perspective view of an exemplary embodiment of a portion of an electronic equipment cabinet including a circuit breaker access.

FIG. 7 depicts a perspective view of an exemplary embodiment of a portion of a closed electronic equipment cabinet including viewing panels

FIGS. 8A-8B depicts a perspective view of an exemplary embodiment of a portion of an electronic equipment cabinet including a seismic mounting system.

FIGS. 9A, 9B and 10 depict a perspective view of an exemplary embodiment of a portion of an electronic equipment cabinet including a cable routing channel.

FIG. 11 depicts a block diagram of a portion of an exemplary embodiment of an electronic equipment cabinet.

### DETAILED DESCRIPTION OF THE PREFERRED EMBODIMENTS

The exemplary embodiments relate to electronic equipment cabinets usable in housing electronic components, such as batteries used in providing reserve power. The following description is presented to enable one of ordinary skill in the art to make and use the invention and is provided in the context of a patent application and its requirements. Various modifications to the exemplary embodiments and the generic principles and features described herein will be readily apparent. The exemplary embodiments are mainly described in terms of particular methods and systems provided in particular implementations. However, the methods and systems will operate effectively in other implementations. Phrases such as “exemplary embodiment”, “one embodiment” and “another embodiment” may refer to the same or different embodiments as well as to multiple embodiments. The embodiments will be described with respect to systems and/or devices having certain components. However, the systems and/or devices may include more or less components than those shown, and variations in the arrangement and type of the components may be made without departing from the scope of the invention. The exemplary embodiments will also be described in the context of particular methods having certain steps. However, the method and system operate effectively for other methods having different and/or additional steps and steps in different orders that are not inconsistent with the exemplary embodiments. Thus, the present invention is not intended to be limited to the embodiments shown, but is to be accorded the widest scope consistent with the principles and features described herein. The electronic equipment cabinet is described in the context of storage of batteries. The electronic equipment cabinet is, therefore, also termed a battery cabinet. However, nothing prevents the use of the electronics cabinet with other electrical components. Although multiple features of the cabinet are described herein, various embodiments may include only a single feature or any combination of features not inconsistent with the method and system described herein.

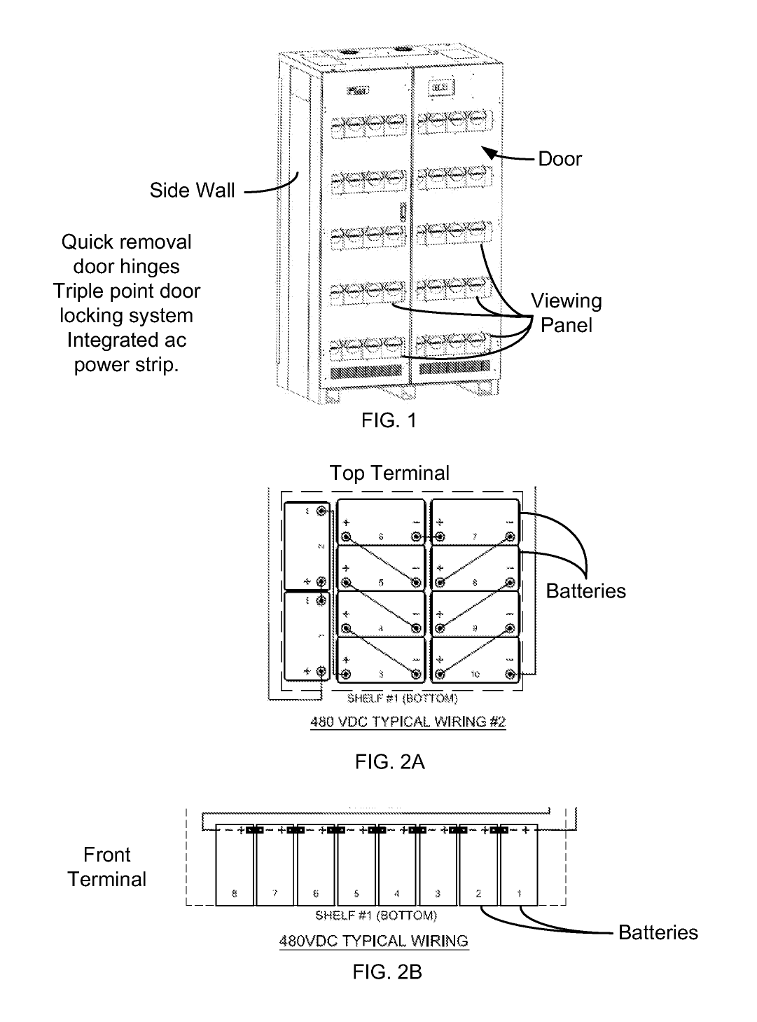

FIG. 1 depicts a perspective view of an exemplary embodiment of an electronic equipment cabinet. In the embodiment shown, the electronic equipment cabinet includes sidewalls, doors, and internal shelves (not explicitly shown in FIG. 1) for holding electronic components such as batteries. In some embodiments, the shelves are moveable to accommodate different battery makes and models. For example, the shelves may be configured to accommodate front terminal and/or top terminal batteries. This feature allows for ease of maintenance and installation of both the batteries and monitoring systems (described below). In some embodiments, opposing sidewalls may include shelf mounting points corresponding to different shelf heights. For example, the shelf mounting points may include apertures for receiving the shelves. The shelves may be configured to fit into apertures in the sidewalls at the desired height and spacing between shelves. In some embodiments, an optional back sidewall may also be used in supporting the selves. In other embodiments, the shelves may be supported by the sidewalls in another fashion. Thus, the combination of the sidewalls and shelves may improve the adaptability of the cabinet to various battery (or other electronic component) configuration.

In some embodiments, the cabinet may be an intelligent cabinet. For example, the cabinet may include a built-in monitoring system for the electronics components within the cabinet. When used to house batteries, the cabinet may incorporate a battery monitor. The battery monitor may be platform independent and thus capable of working with virtually any brand of batteries with minimal alterations. The monitor may determine temperature, remaining power, and/or other attributes of the batteries. These characteristics may, for example, be used in determining the lifetime of the battery. The electronics cabinet may also include a separate temperature sensor. In some embodiments, the cabinet may also have an active heat dissipation system. More specifically, the cabinet may include fans used to improve heat dissipation, particularly if a rise in temperature of the batteries beyond a threshold is detected by the temperature sensor. Thus, the cabinet may be considered to be an intelligent cabinet because of the presence of the battery monitor system and/or temperature sensor and heat dissipation system.

The cabinet may also include doors for securing the batteries and/or other components housed within the cabinet. In some embodiments, the cabinet also includes viewing panels (of which only a few are labeled in FIG. 1). The viewing panels may be in the doors (as shown) and/or sidewalls (including the rear sidewall, if any). The viewing panels may be composed of polycarbonate or other transparent or translucent material. Alternatively, the viewing panels may simply be apertures in the door(s). The viewing panels may allow the user to view the batteries, battery monitor, temperature sensor, batteries or other components while the doors are closed.

The cabinet may also include various other features. For example, the cabinet also allows for safe and easy access to the system breaker without opening the cabinet doors through the use of a breaker panel. The breaker panel may include a translucent or transparent cover. Some embodiments include an internal cable tray for managing and housing cables used to connect to/between the batteries and/or other internal components. The bottom of the cabinet may include a seismic mounting kit. The seismic mounting kit may allow the cabinet to be locked in place in the event of an earthquake. The cabinet might include an internal cable routing channel through which electrical cables may be routed to various components within and external to the cabinet. The cabinet may include an integrated AC power strip to which components stored in the cabinet or external electronic component may be connected. The cabinet includes doors may be connected to the sidewalls using quick removal hinges for rapid removal of the doors. In some embodiments, the doors may also include a triple point locking system that allows for easy locking an unlocking/opening of the doors.

FIGS. 2A-2B depict exemplary embodiments of possible battery arrangements in a shelf of an electronic equipment cabinet, such as the cabinet depicted in FIG. 2A depicts one embodiment of a configuration of top terminal batteries on a particular shelf. In such an embodiment, four shelves of ten batteries each may be contained in the cabinet. FIG. 2B depicts an embodiment of a configuration for front terminal batteries. In such an embodiment, five shelves of eight batteries per shelf may be contained in the cabinet. In other embodiments, the top terminal and/or front terminal batteries may be arranged in another manner. For example, front terminal and top terminal batteries may be stored together in a single shelf. In either embodiment, the cabinet may allow for easy shelf removal and reinstallation to accommodate both top and front access terminal batteries as well as batteries from multiple of different vendors. This may accomplished by having various shelf mounting points in the interior of the cabinet. The shelf mounting points may include apertures in the sidewalls or another mechanism for supporting the shelf at the desired height. By selecting the shelf mounting points used, the location and number of shelves may be varied.

In addition to having the number, location, and height of the shelves configured, the arrangement of components within a shelf may be optimized. For example, removable shelf templates may be provided. The shelf templates indicate the specific pattern that may be desired for various make/models of battery types. The removable template allows the locations of batteries or other components in a shelf to be optimized and provided to the user. For example, the shelf template for top access batteries may indicate the configuration shown in FIG. 2A. Using this shelf mounting and template flexibility, the cabinet may be more easily re-utilized even if major changes are made from one battery replacement cycle to the next.

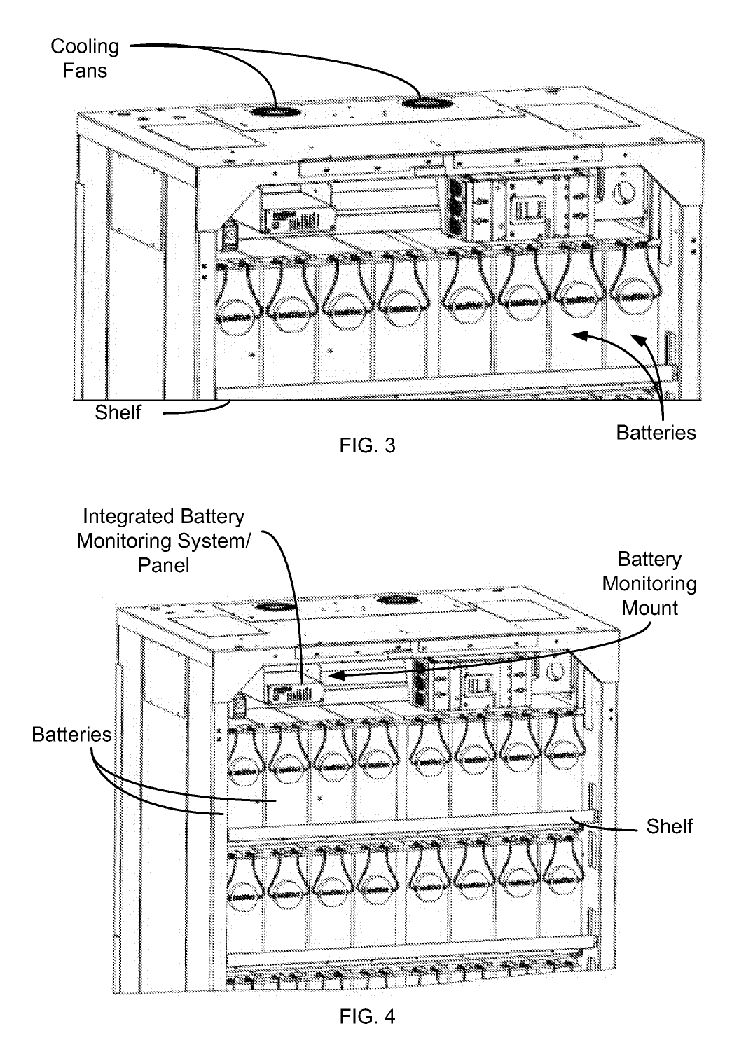

FIG. 3 depicts a perspective view of the top of an open electronic equipment cabinet including cooling fans. In the embodiment shown, there are multiple, redundant fans to assist in dissipating warm air within the cabinet. Although two fans are shown, another number may be used. In some embodiments, only one fan is provided. In other embodiments, more than two fans might be used. Further, a cooling mechanism other than fans might be used. The battery system may thus be cooled. The fan(s) may be triggered by either an internal thermostat (internal to the cabinet) or the built-in battery monitoring platform discussed below. In some embodiments, the monitoring system monitors temperature of each battery using sensors in or near each of the batteries. Control logic may be separately included or incorporated into the battery monitoring system discussed below. The control logic may trigger the fan(s) based on the readings of the temperature sensor(s). The fan(s) may be turned off when the temperature drops below a threshold, based on the time the fan has been on, or through another mechanism. One or more of the fans or other cooling mechanisms may be controlled by the battery monitoring system to cool specific areas having a higher temperature. Thus, temperature within the cabinet may be controlled with a high degree of accuracy. Further, target specific problematic area(s) (hot spots) may be targeted for cooling using the combination of measurement granularity (every battery) and the cooling mechanism granularity (multiple cooling elements). By actively keeping the battery system cooler, the life of the battery system may be extended.

In some embodiments CFD (Computational Fluid Dynamics) algorithms may be applied to the cabinet. Using CFD and the cooling elements (fan(s)), a chimney effect may be created by drawing air from below with or without the use of optional filtration systems. Further, airflow may be channeled between each adjoining battery throughout the system. The warm air may be removed through the “chimney” outlets on the top of the cabinet. Using CFD the airflow through the cabinet may be optimized for cooling the desired configuration of batteries. Thus, the lives of the batteries may be further extended.

FIG. 4 depicts a perspective view of an open electronics cabinet including an integrated battery monitoring system. In the embodiment shown, the cabinet has an onboard monitoring portal including a mount where the battery monitoring panel, power and communications may be integrated in the frame of the cabinet. The battery monitoring system may include sensors and/or other components mounted on each of the batteries. Alternatively, the sensors and/or other components may be mounted on the cabinet in proximity to the batteries. The battery monitoring panel may communicate with these sensor and/or other components. The need for unsightly aftermarket monitoring equipment may be reduced or eliminated. The platform independent battery monitoring portal may be flexible enough to accommodate any brand of battery monitor with a simple mounting kit specific to each make. The battery monitoring system may be used in conjunction with the temperature sensors and fans discussed previously. Other sensors internal to the cabinet and/or batteries may also be used to provide input to the battery monitoring system. By including onboard intelligence in the battery cabinet end-users may be able to better predict the health and life of their battery asset.

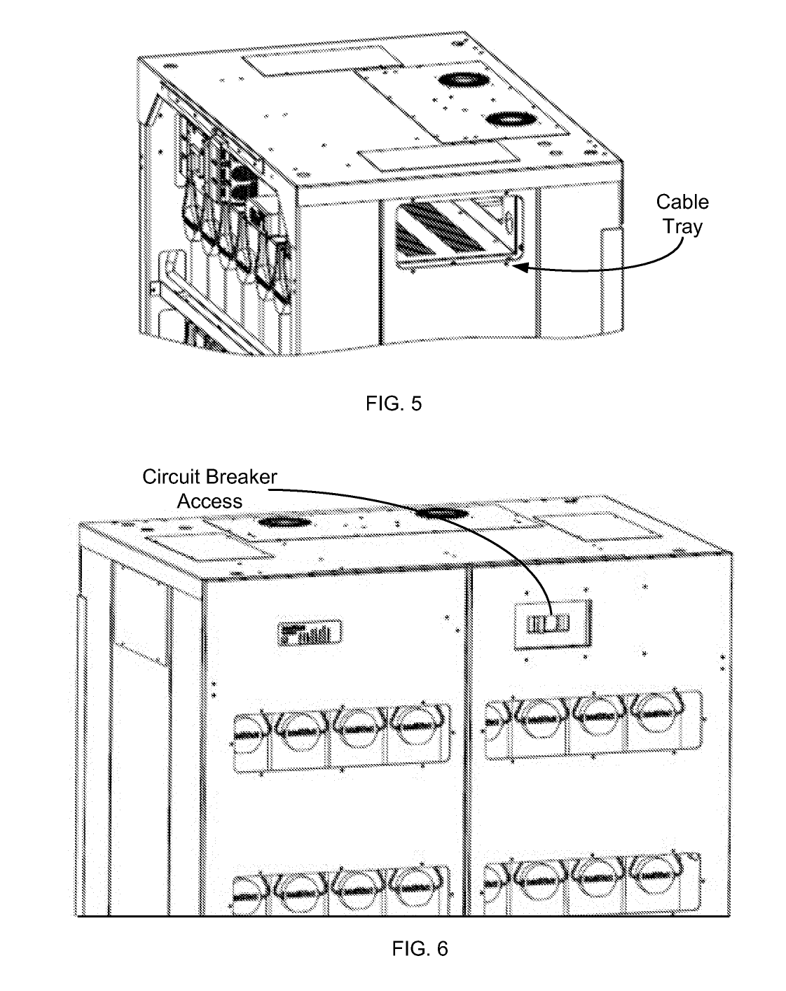

FIG. 5 depicts a perspective view of a portion of an electronics cabinet including a cable tray. The cable tray may be used in connecting multiple cabinets together. The integrated cable tray may route and support the power cables that are passed through each cabinet to the next. This provides a clean and safe system to contain said cables as well as improved safety while working in cabinet. Alternatively, the cable tray may be used in routing cables internal to the cabinet.

FIG. 6 depicts a perspective view of a portion of an electronics cabinet including a circuit breaker access panel and cover. In the embodiment shown, the access cover is a sliding clear plastic safety cover that protects the breaker. In other embodiments, another type of cover may be used. The cover aids in ensuring that there is an extra, explicit human safety step in activating or deactivating the breaker. Further, the cover may be transparent or translucent. This allows the user to view and or operate the battery breaker without opening the cabinet door. Furthermore, by not opening the cabinet door, the person operating the breaker is shielded if a breaker fault or other dangerous condition were to occur.

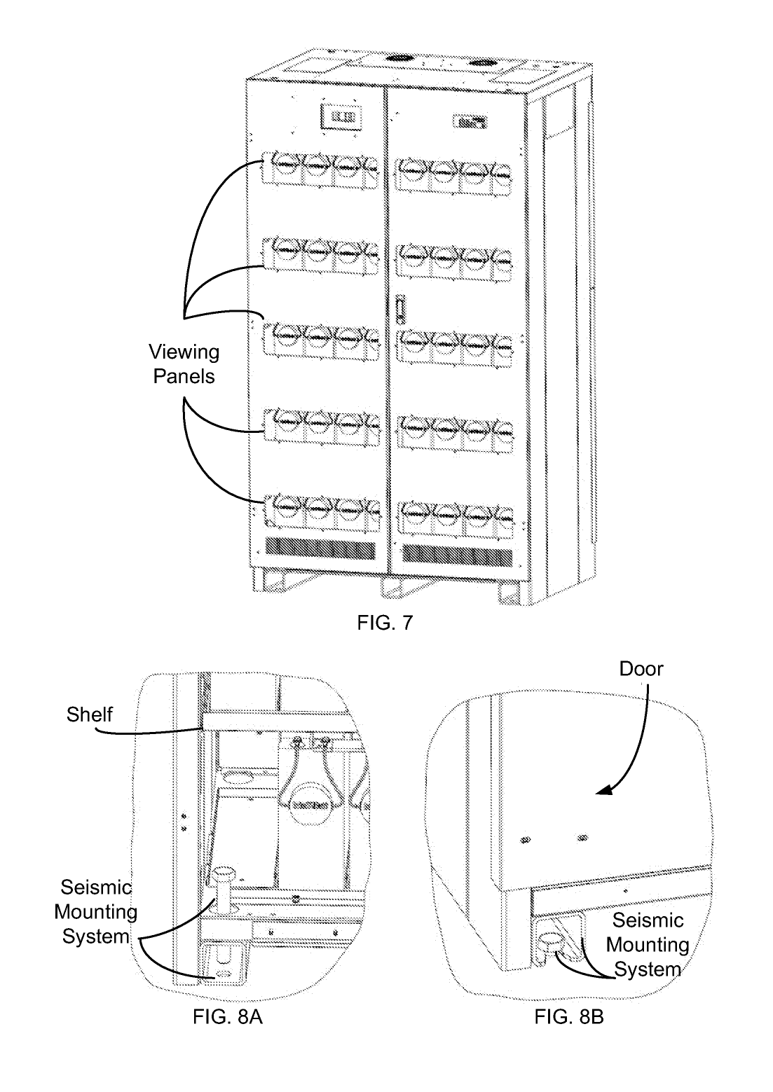

FIG. 7 depicts a perspective view of a portion of a closed electronics cabinet including viewing panels. In the embodiment shown, the viewing panels reside only in the door. However, in other embodiments, one or more viewing panels might be incorporated into the sidewalls. In the embodiment shown, the viewing panels are polycarbonate. However, another material may be used. Alternatively, the viewing panels may simply be apertures. The polycarbonate viewing panels shown allow the user to view the state of one or more of the batteries, the terminal mounting hardware, the interconnects and the monitoring systems without opening the cabinet doors. In some embodiments, the battery monitoring system may include an LED(s) on one or more of the batteries. In such a case, the LED indicates the state of health of the battery. Such LEDs or like devices may also be visible through the viewing panels. Visual inspection of the batteries or other components in the cabinet may thus be more efficient. For example, the panels may improve efficiency by reducing time during inspections.

FIGS. 8A-8B depict perspective views of a portion of an electronics cabinet including a seismic mounting system. In the embodiment shown, the seismic mounting system is a slide in place mounting plate system. The mounting system allows the user to bolt the mounting plate to a concrete slab under the cabinet and slide the cabinet into place. The rear of the cabinet is thus locked in place. Once the front mounting points are secured the cabinet may meet Zone 4 seismic requirements. Thus, safety and reliability of the cabinet may be improved.

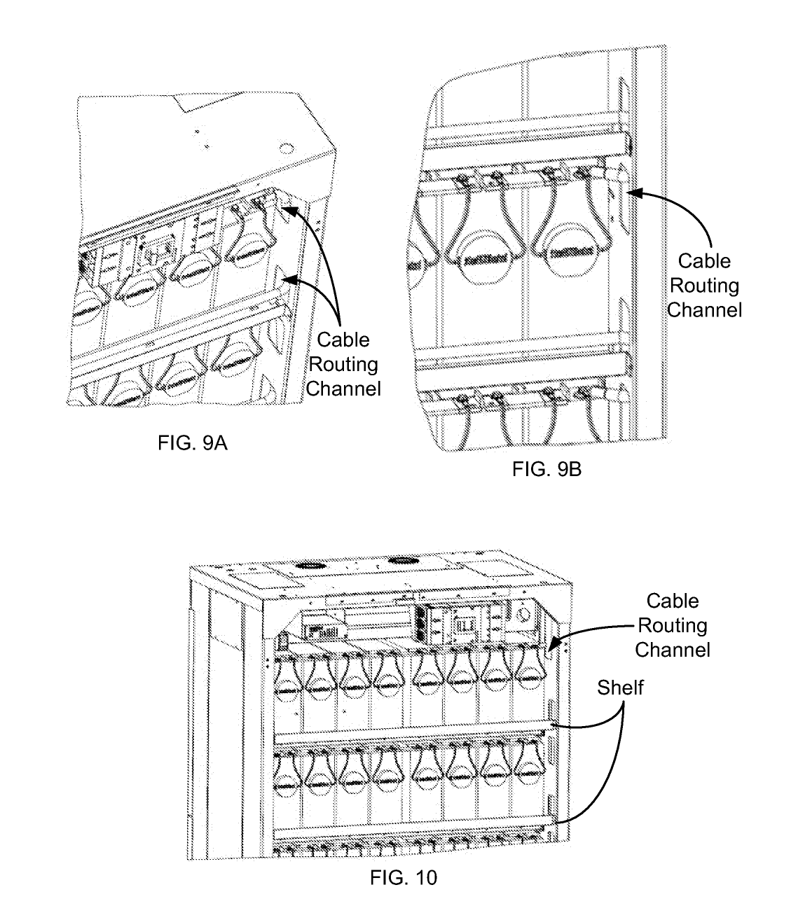

FIGS. 9A, 9B and 10 depict perspective views of a portion of an electronics cabinet including at least one cable routing channel. In other embodiments, multiple internal cable routing channels may be used. The internal channels may route inter-tier cabling within the cabinet structure in an organized, safe manner. More specifically, the cables our routed through the channel and thus are safely out of the way. The channels may thus allow for maintenance and battery replacements to be performed more easily.

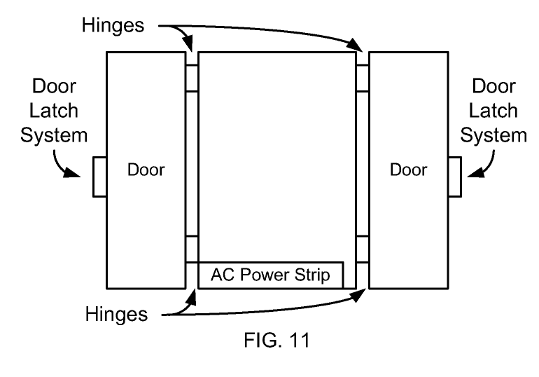

FIG. 11 depicts a block diagram of a portion of an exemplary embodiment of an electronics cabinet. The cabinet includes an AC power strip incorporated into the cabinet. The AC power strip may be located at the bottom of the cabinet, as shown, on a sidewall, or at another location. Further, multiple AC power strips might be provided. The AC power strip may be used to power additional equipment in or around the cabinet. The AC power strip also provides the AC current used to power the on-board battery monitoring system discussed above. Also shown are hinges for the cabinet doors. In some embodiments, wide swing angle hinges are used. Such hinges may allow the user to easily remove the cabinet doors to more readily access the equipment inside. A door latch system is also shown. The door latch system may be used to ensure that the cabinet doors remain closed and to facilitate opening when desired. In some embodiments, the door latch system is a triple point door locking system that allows the user to open the cabinet with one turn of a handle without the user releasing or unscrewing an additional latching point inside.

A method and system for providing an electronic equipment cabinet usable in storing reserve power batteries has been described. The method and system have been described in accordance with the exemplary embodiments shown, and one of ordinary skill in the art will readily recognize that there could be variations to the embodiments, and any variations would be within the spirit and scope of the method and system. Accordingly, many modifications may be made by one of ordinary skill in the art without departing from the spirit and scope of the appended claims.

We claim:

1. An electronic equipment cabinet comprising:
a plurality of sidewalls including a pair of opposing sidewalls, each of the opposing sidewalls including a plurality of shelf mounting points;
a plurality of shelves configured to be received at the plurality of shelf mounting points such that the plurality of shelves is configurable to accommodate a plurality of components.

2. The electronic equipment cabinet of claim 1 wherein the plurality of components include at least one of top access batteries and front access batteries.

3. The electronic equipment cabinet of claim 2 wherein the plurality of shelves includes a plurality of templates for positioning the plurality of components on the plurality of shelves.

4. The electronic equipment cabinet of claim 1 further comprising:
at least one fan; and
at least one temperature sensor, the at least one fan being activated and deactivated based upon a signal from the at least one temperature sensor.

5. The electronic equipment cabinet of claim 4 wherein the at least one fan is controlled based on computational fluid dynamics.

6. The electronic equipment cabinet of claim 1 wherein the plurality of components includes a plurality of batteries, the electronics cabinet further comprising:
at least one battery monitoring system for communicating with a plurality of battery sensors.

7. The electronic equipment cabinet of claim 6 wherein the plurality of sensors are on a plurality of batteries.

8. The electronic equipment cabinet of claim 7 wherein the plurality of sensors are coupled with a plurality of indicators for the plurality of batteries and wherein the electronics cabinet further includes:
at least one door including at least one viewing panel through which the plurality of indicators is visible.

9. The electronic equipment cabinet of claim 1 further comprising:
at least one door including at least one viewing panel.

10. The electronic equipment cabinet of claim 9 wherein the at least one viewing panel includes a polycarbonate window.

11. The electronic equipment cabinet of claim 1 further comprising. an internal cable tray configured to receive cables from at least one adjoining electronics cabinet.

12. The electronic equipment cabinet of claim 1 further comprising. an internal cable routing channel configured to route cables within the electronic equipment cabinet.

13. The electronic equipment cabinet of claim 1 further comprising:
at least one breaker panel configured to retain at least one circuit breaker; and
at least one cover through which the at least one circuit breaker is visible.

14. The electronic equipment cabinet of claim 1 further comprising:
a seismic mounting subsystem configured to secure the electronics cabinet to a floor.

15. The electronic equipment cabinet of claim 1 further comprising:
an integrated alternating current power strip.

16. The electronic equipment cabinet of claim 1 further comprising:
at least one door; and
a plurality of quick removal hinges connecting the at least one door to at least one of the plurality of sidewalls

17. The electronic equipment cabinet of claim 1 further comprising:
at least one door connected to at least one of the plurality of sidewalls; and
a triple point door locking system coupled with the at least one door.
